(19) United States
(12) Patent Application Publication
(10) Pub. No.: US 2026/0076137 A1
(43) Pub. Date: Mar. 12, 2026

(54) Substrate Processing Apparatus, Substrate Processing Method, Method of Manufacturing Semiconductor Device and Non-transitory Computer-readable Recording Medium

(71) Applicant: Kokusai Electric Corporation, Tokyo (JP)

(72) Inventor: Kaoru YAMAMOTO, Toyama (JP)

(21) Appl. No.: 19/343,334

(22) Filed: Sep. 29, 2025

Related U.S. Application Data
(63) Continuation of application No. PCT/JP2024/012879, filed on Mar. 28, 2024.

(30) Foreign Application Priority Data
Sep. 20, 2023 (JP) 2023-152919

(51) Int. Cl. H01L 21/67; B25J 11/00; H01L 21/687

(52) U.S. Cl. CPC H10P 72/0461; B25J 11/0095; H10P 72/0454; H10P 72/7602

(57) ABSTRACT

There is provided a technique that includes: an atmospheric transfer structure configured to transfer a substrate in an atmospheric atmosphere; a plurality of processing structures arranged along the atmospheric transfer structure and configured to be capable of processing the substrate in a vacuum atmosphere; an intermediate structure arranged adjacent to the plurality of processing structures, and configured to receive the substrate from the atmospheric transfer structure and to transfer the substrate to each of the plurality of processing structures in an atmosphere whose pressure is lower than that of the atmospheric atmosphere.

### CROSS REFERENCE TO RELATED APPLICATIONS

This application is a bypass continuation application of PCT International Application No. PCT/JP2024/012879, filed on Mar. 28, 2024, in the WIPO, the international application being based upon and claiming the benefit of priority from Japanese Patent Application No. 2023-152919, filed on Sep. 20, 2023, in the Japanese Patent Office, the entire contents of which are hereby incorporated by reference.

### TECHNICAL FIELD

The present disclosure relates to a substrate processing apparatus, a substrate processing method, a method of manufacturing a semiconductor device and a non-transitory computer-readable recording medium.

### BACKGROUND

According to some related arts, a substrate processing apparatus provided with a plurality of process chambers may be used. In each process chamber, a substrate (or a plurality of substrates) can be processed.

There is a market demand to increase a productivity of a substrate processing.

### SUMMARY

According to the present disclosure, there is provided a technique capable of improving a productivity of a substrate processing.

According to an embodiment of the present disclosure, there is provided a technique that includes: an atmospheric transfer structure configured to transfer a substrate in an atmospheric atmosphere; a plurality of processing structures arranged along the atmospheric transfer structure and configured to be capable of processing the substrate in a vacuum atmosphere; an intermediate structure arranged adjacent to the plurality of processing structures, and configured to receive the substrate from the atmospheric transfer structure and to transfer the substrate to each of the plurality of processing structures in an atmosphere whose pressure is lower than that of the atmospheric atmosphere.

### BRIEF DESCRIPTION OF THE DRAWINGS

FIG. 1 is a diagram schematically illustrating a vertical cross-section of an exemplary configuration of a substrate processing apparatus according to a first embodiment of the present disclosure.

FIG. 2 is a diagram schematically illustrating a horizontal cross-section of the substrate processing apparatus, taken along a line α-α shown in FIG. 1.

FIG. 3 is a diagram schematically illustrating a vertical cross-section of the substrate processing apparatus, taken along a line β-β shown in FIG. 1.

FIG. 4 is a diagram schematically illustrating a vertical cross-section of the substrate processing apparatus, taken along a line γ-γ shown in FIG. 1.

FIG. 5 is a diagram schematically illustrating a vertical cross-section of an exemplary configuration of a reactor in FIG. 1.

FIG. 6A is a diagram schematically illustrating an exemplary configuration of a first gas supplier provided in the reactor shown in FIG. 5.

FIG. 6B is a diagram schematically illustrating an exemplary configuration of a second gas supplier provided in the reactor shown in FIG. 5.

FIG. 6C is a diagram schematically illustrating an exemplary configuration of an inert gas supplier provided in the reactor shown in FIG. 5.

FIG. 6D is a diagram schematically illustrating an exemplary configuration of an inert gas supplier provided in an intermediate structure shown in FIG. 4.

FIG. 7 is a block diagram schematically illustrating a configuration of a controller and its related components of the substrate processing apparatus according to the first embodiment of the present disclosure.

FIG. 8 is a diagram (corresponding to FIG. 4) schematically illustrating a vertical cross-section of an exemplary configuration of a substrate processing apparatus according to a second embodiment of the present disclosure.

FIG. 9 is a diagram schematically illustrating a vertical cross-section of an exemplary configuration of a reactor in FIG. 8.

FIG. 10 is a diagram (corresponding to FIG. 2) schematically illustrating a horizontal cross-section of the exemplary configuration of the substrate processing apparatus according to the second embodiment of the present disclosure.

FIG. 11 is a diagram schematically illustrating a vertical cross-section of the exemplary configuration of the reactor in FIG. 10.

FIG. 12 is a diagram (corresponding to FIG. 2) schematically illustrating a horizontal cross-section of an exemplary configuration of a substrate processing apparatus according to a third embodiment of the present disclosure.

### DETAILED DESCRIPTION

Hereinafter, embodiments of the technique of the present disclosure will be described in detail with reference to the drawings. The drawings used in the following descriptions are all schematic. For example, a relationship between dimensions of each component and a ratio of each component shown in the drawing may not always match the actual ones. In addition, even between the drawings, the relationship between the dimensions of each component and the ratio of each component may not always match.

### First Embodiment

### (1) Configuration of Substrate Processing Apparatus

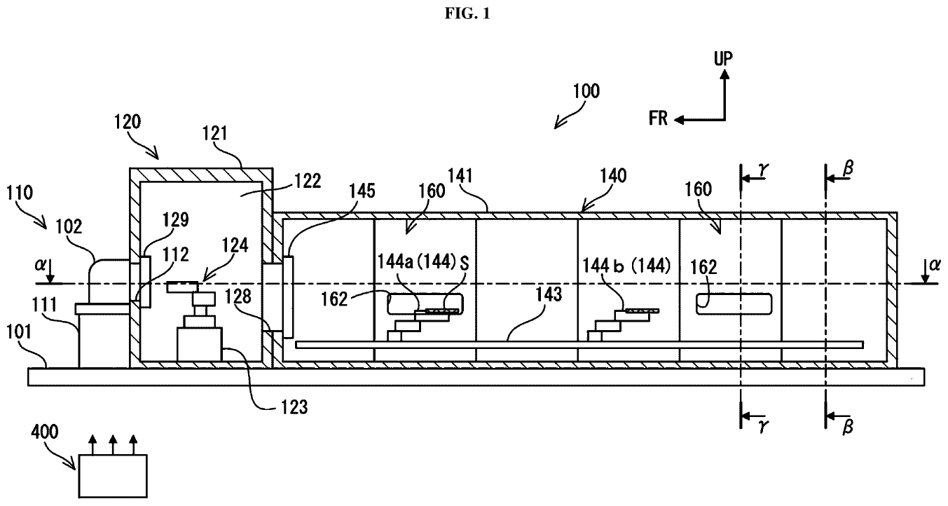

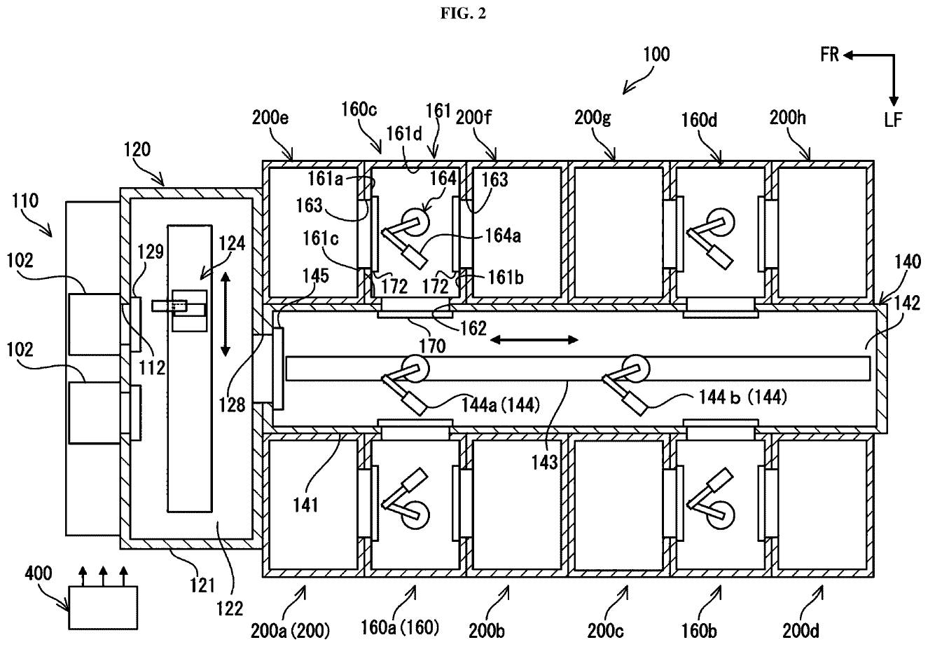

A schematic configuration of a substrate processing apparatus according to a first embodiment of the present disclosure will be described with reference to FIGS. 1 and 2. FIG. 1 is a diagram schematically illustrating a vertical cross-section of an exemplary configuration of the substrate processing apparatus according to the first embodiment of the present disclosure. FIG. 2 is a diagram schematically illustrating a horizontal cross-section of the exemplary configuration of the substrate processing apparatus according to the first embodiment of the present disclosure, taken along a line α-α shown in FIG. 1.

In FIGS. 1 and 2, a substrate processing apparatus 100 according to the present embodiment is shown. The substrate processing apparatus 100 is configured to process a substrate S serving as a substrate (wafer). This substrate processing apparatus 100 includes a loading port structure 110, a first transfer structure 120, a second transfer structure 140, a plurality of reactors 200, a plurality of intermediate structures 160 and a controller 400. The second transfer structure 140 according to the present embodiment serves as an example of an atmospheric transfer structure according to the present disclosure. The reactors 200 according to the present embodiment serve as an example of a processing structure according to the present disclosure.

In addition, in the following, for convenience of explanation, in FIG. 1, a direction, indicated by an arrow FR, of the substrate processing apparatus 100 may also be referred to as “front” (front side) of the substrate processing apparatus 100, a direction opposite to the arrow FR may also be referred to as “rear” (rear side) of the substrate processing apparatus 100, a direction indicated by an arrow UP may also be referred to as “up” (upper side) of the substrate processing apparatus 100, and a direction opposite to the arrow UP may also be referred to as “down” (lower side) of the substrate processing apparatus 100. In addition, in FIG. 2, a direction, indicated by an arrow LF, of the substrate processing apparatus 100 may also be referred to as “left” (left side) of the substrate processing apparatus 100, and a direction opposite to the arrow LF may also be referred to as “right” (right side) of the substrate processing apparatus 100. In addition, “front” (front side), “rear” (rear side), “up” (upper side), “down” (lower side), “left” (left side) and “right” (right side) of the substrate processing apparatus 100 may also be simply referred to as “front” (front side), “rear” (rear side), “up” (upper side), “down” (lower side), “left” (left side) and “right” (right side), respectively. In addition, a left-right direction of the substrate processing apparatus 100 may also be referred to as a “width direction” or a “horizontal direction”, a front-rear direction of the substrate processing apparatus 100 may also be referred to as a “depth direction”, and an up-down direction of the substrate processing apparatus 100 may be referred to as a “height direction”.

As shown in FIGS. 1 and 2, the substrate processing apparatus 100 is provided with the loading port structure 110 and the first transfer structure 120 arranged at a front portion of the substrate processing apparatus 100. In addition, the substrate processing apparatus 100 is further provided with the second transfer structure 140 arranged from the first transfer structure 120 toward a rear portion of the substrate processing apparatus 100. Specifically, the second transfer structure 140 is arranged at a central portion in the width direction of the substrate processing apparatus 100 and extends from the first transfer structure 120 toward the rear portion of the substrate processing apparatus 100. The plurality of reactors 200 and the plurality of intermediate structures 160 are arranged on both sides of a width direction of the second transfer structure 140. According to the present embodiment, for example, four reactors 200 are arranged on one side (left side) of the width direction of the second transfer structure 140, and four reactors 200 are arranged on the other side (right side) of the width direction of the second transfer structure 140. When the reactors 200 are individually specified, the four reactors 200 on the left side from front to rear may also be referred to as a reactor 200a, a reactor 200b, a reactor 200c and a reactor 200d, respectively, and the four reactors 200 on the right side from front to rear may also be referred as a reactor 200e, a reactor 200f, a reactor 200g and a reactor 200h, respectively. According to the present embodiment, for example, two intermediate structures 160 are arranged on one side (left side) of the width direction of the second transfer structure 140, and two intermediate structures 160 are arranged on the other side (right side) of the width direction of the second transfer structure 140. When the intermediate structures 160 are individually specified, the two intermediate structures 160 on the left side from front to rear may also be referred to as an intermediate structure 160a and an intermediate structure 160b, respectively, and the two intermediate structures 160 on the right side from front to rear may also be referred to as an intermediate structure 160c and an intermediate structure 160d, respectively. Hereinafter, each of the reactors 200 may also be referred to as a “reactor 200”, and each of the intermediate structures 160 may also be referred to as an “intermediate structure 160”.

In addition, the loading port structure 110, the first transfer structure 120, the second transfer structure 140, the intermediate structures 160 and the reactors 200 are fixed to a floor 101.

Subsequently, components constituting the substrate processing apparatus 100 will be described in detail. In addition, operations of the components of the substrate processing apparatus 100 are controlled by the controller 400 described later.

### <Loading Port Structure>

As shown in FIG. 1, the loading port structure 110 is installed in the front portion of the substrate processing apparatus 100. A plurality of support tables 111 are provided at the loading port structure 110. Hereinafter, each of the support tables 111 may also be referred to as a “support table 111”. A storage container 102 serving as an example of a container is mounted (placed) on the support table 111. The storage container 102 is a container capable of accommodating (storing) a plurality of substrates including the substrate S such as a silicon (Si) substrate. Hereinafter, the plurality of substrates including the substrate S may also be referred to as “substrates S.” The storage container 102 may also be referred to as a “FOUP” (which is a Front Opening Unified Pod), a “cassette” and the like.

### <First Transfer Structure>

As shown in FIG. 1, the first transfer structure 120 is provided adjacent to the loading port structure 110 in rear of (behind) the loading port structure 110. In addition, the first transfer structure 120 is provided adjacent to the reactor 200 opposite to the loading port structure 110. Specifically, the first transfer structure 120 is provided adjacent to the reactor 200a and the reactor 200e.

The first transfer structure 120 is a structure (component) in the substrate processing apparatus 100, and configured to transfer the substrate S between the loading port structure 110 and the second transfer structure 140. In other words, the first transfer structure 120 is a structure in the substrate processing apparatus 100, and configured to transfer the substrate S between the storage container 102 and a second transfer robot 144 (specifically, a front side second transfer robot 144a). The first transfer structure 120 transfers the substrate S in an atmospheric atmosphere (air atmosphere).

The first transfer structure 120 is provided with a housing 121. An inside (inner portion) of the housing 121 is configured as a transfer space 122 through which the substrate S is transferred. In addition, a first transfer rail 123 extending in a lateral direction is provided at a lower portion (bottom) of the housing 121.

In a front portion of the housing 121, a loading/unloading port 112 is provided. The substrate S is transferred from the storage container 102 on the loading port structure 110 into the housing 121 through the loading/unloading port 112. An opener 129 configured to open a lid of the storage container 102 is provided at the loading/unloading port 112. In addition, the opener 129 is provided opposite to the second transfer structure 140.

In a rear portion of the housing 121, a loading/unloading port 128 is provided. The substrate S is transferred from the housing 121 into a housing 141 of the second transfer structure 140 through the loading/unloading port 128. The loading/unloading port 128 is opened and closed by a shutter 145.

In addition, in the first transfer structure 120, a first transfer robot 124 capable of transferring the substrate S between the storage container 102 and the second transfer robot 144 (that is, the front side second transfer robot 144a) described later. In other words, the first transfer structure 120 is provided with the first transfer robot 124 in the housing 121.

The first transfer robot 124 is capable of being moved on the first transfer rail 123 along the first transfer rail 123. The first transfer robot 124 is configured to be capable of mounting thereon a single substrate S.

An operation of the first transfer robot 124 is controlled by the controller 400. For example, the controller 400 can control the first transfer robot 124 to transfer the substrate S between the storage container 102 supported by the loading port structure 110 and the second transfer robot 144 (specifically, the front side second transfer robot 144a). Specifically, the first transfer robot 124 can receive an unprocessed substrate (among the substrates S) from the storage container 102 and pass the unprocessed substrate to the second transfer robot 144 (front side second transfer robot 144a), and can receive a processed substrate (among the substrates S) from the second transfer robot 144 (front side second transfer robot 144a) and pass the processed substrate to the storage container 102. Hereinafter, the unprocessed substrate among the substrates S may also be referred to as an “unprocessed substrate S,” and the processed substrate among the substrates S may also be referred to as a “processed substrate S.”

### <Second Transfer Structure>

As shown in FIG. 1, the second transfer structure 140 is arranged from the first transfer structure 120 toward the rear portion of the substrate processing apparatus 100. In addition, the plurality of reactors 200 and the plurality of intermediate structures 160 are arranged on both sides of the width direction of the second transfer structure 140.

The second transfer structure 140 is configured to be capable of communicating with the plurality of intermediate structures 160. The second transfer structure 140 is a structure in the substrate processing apparatus 100, and configured to transfer the substrate S between the first transfer structure 120 and each of the intermediate structures 160. In other words, the second transfer structure 140 is a structure in the substrate processing apparatus 100, and configured to transfer the substrate S between the first transfer robot 124 and a third transfer robot 164 serving as an example of an intermediate transfer robot. The second transfer structure 140 transfers the substrate S in the atmospheric atmosphere.

The second transfer structure 140 is provided with the housing 141. An inside (inner portion) of the housing 141 is configured as a transfer space 142 through which the storage container 102 is transferred.

In a front portion of the housing 141, the loading/unloading port 128 is provided. The shutter 145 is provided in the vicinity of the loading/unloading port 128.

In addition, a second transfer rail 143 along which the second transfer robot 144 is moved is provided at a lower portion of the housing 141. Specifically, the second transfer rail 143 is provided at a lower portion of the housing 141, and extends in the front-rear direction. In other words, the second transfer rail 143 extends in a straight line from the loading/unloading port 128 toward the rear portion of the substrate processing apparatus 100.

In addition, in the second transfer structure 140, the second transfer robot 144 serving as an example of an atmospheric transfer robot capable of transferring the substrate S to each of the intermediate structures 160 is provided. In other words, the second transfer structure 140 is provided with the second transfer robot 144 in the housing 141. In addition, according to the present embodiment, the second transfer structure 140 is provided with the second transfer robot 144. However, the technique of the present disclosure is not limited to such a configuration. For example, the second transfer structure 140 may be provided with a plurality of second transfer robots including the second transfer robot 144. Hereinafter, the plurality of second transfer robots including the second transfer robot 144 may also be referred to as “second transfer robots 144”.

The second transfer robot 144 is capable of being moved on the second transfer rail 143 along the second transfer rail 143. The second transfer robot 144 is configured to be capable of mounting thereon a single substrate S. In other words, the second transfer robot 144 is capable of being moved along the second transfer rail 143 while supporting (holding) the substrate S, and capable of transferring the substrate S to the intermediate structure 160 to which the substrate S is to be transferred.

In addition, according to the present embodiment, the second transfer structure 140 may be provided with the second transfer robots 144. The intermediate structures 160 are in charge of the second transfer robots 144. Specifically, the second transfer structure 140 is provided with two second transfer robots 144, and on the second transfer rail 143, one of the two second transfer robots 144 is provided in front of the other one of the two second transfer robots 144. In the following, one of the two second transfer robots 144 arranged on the front side may also be referred to as the “front side second transfer robot 144a”, and the other one of the two second transfer robots 144 arranged on the rear side may also be referred to as a “rear side second transfer robot 144b”. In addition, the front side second transfer robot 144a and the rear side second transfer robot 144b are configured to be capable of transferring the substrate S between each other.

The front side second transfer robot 144a according to the present embodiment is in charge of the intermediate structure 160 arranged on the front side among the plurality of intermediate structures 160. Specifically, the front side second transfer robot 144a in charge of the intermediate structure 160a and the intermediate structure 160c. In other words, the front side second transfer robot 144a transfers the substrate S to the intermediate structure 160a or 160c.

The rear side second transfer robot 144b according to the present embodiment is in charge of the intermediate structure 160 arranged on the rear side among the plurality of intermediate structures 160. Specifically, the rear side second transfer robot 144b is in charge of the intermediate structure 160b and the intermediate structure 160d. In other words, the rear side second transfer robot 144b transfers the substrate S to the intermediate structure 160b or 160d.

In addition, the intermediate structure 160 in charge of the front side second transfer robot 144a or the rear side second transfer robot 144b is not limited to an example mentioned above, and may be changed as appropriate depending on a circumstance such as process conditions.

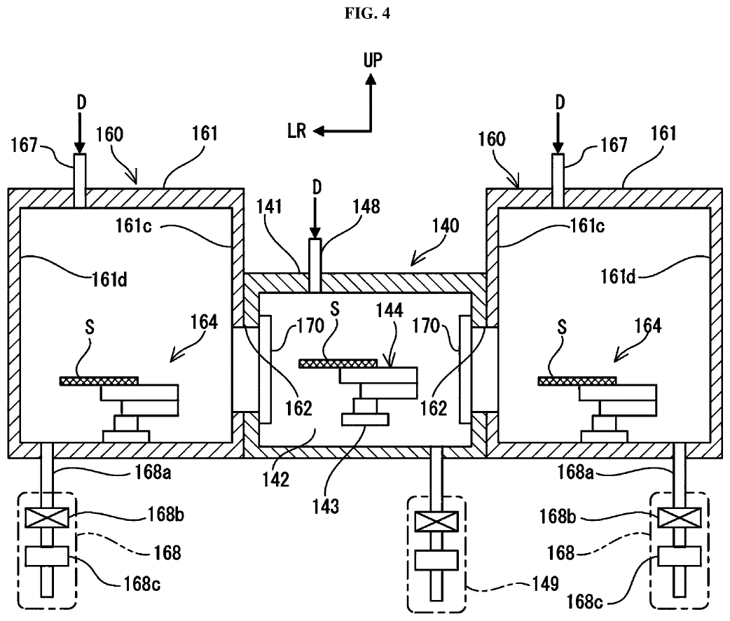

In addition, as shown in FIG. 4, the second transfer structure 140 is provided with an inert gas supplier (which is an inert gas supply structure) 148 and an exhauster (which is an exhaust structure) 149. The inert gas supplier 148 is a structure configured to supply an inert gas into the housing 141. By supplying the inert gas into the housing 141, it is possible to adjust (or set) an atmosphere (inner atmosphere) of the transfer space 142 to an inert gas atmosphere. In addition, the exhauster 149 is a structure configured to exhaust an atmosphere (inner atmosphere) of the housing 141.

The operation of the second transfer robot 144 is controlled by the controller 400. For example, the controller 400 is configured to set transfer areas (that is, the intermediate structures 160 in charge) of the second transfer robots 144. The controller 400 is configured to control the operation of the second transfer robot 144 such that the substrate S is transferred between the first transfer robot 124 and the third transfer robot 164.

### <Reactor: Single Wafer Type Apparatus>

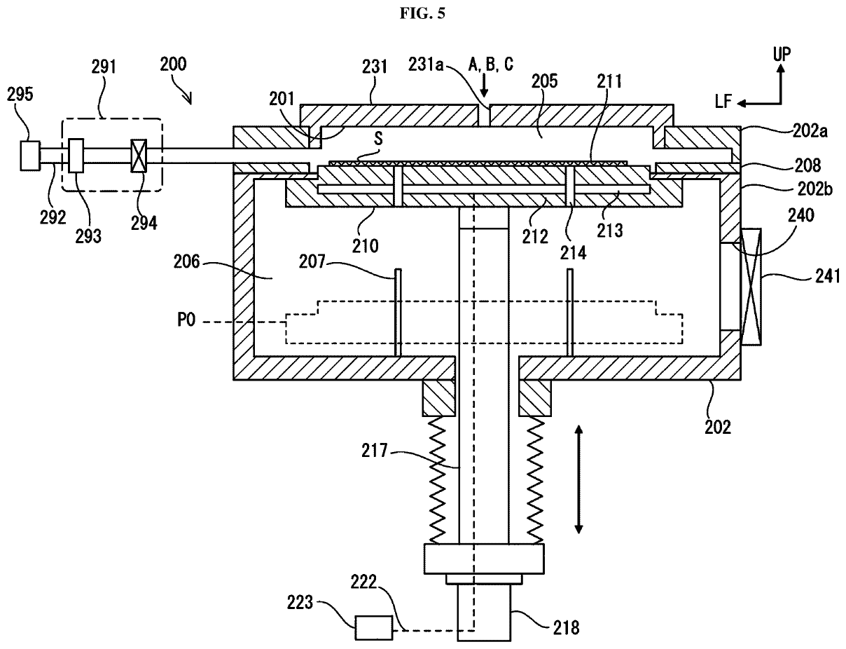

Subsequently, the reactor 200 will be described with reference to FIG. 5. As shown in FIGS. 2 to 4, the plurality of reactors 200 are arranged along both side surfaces of the housing 141 of the second transfer structure 140. The reactor 200 serves as a module (structure) capable of processing the substrate S in a vacuum atmosphere. In addition, according to the present embodiment, the intermediate structure 160 is arranged for every two reactors 200.

The reactor 200 is provided with a vessel 202. In the vessel 202, a process chamber 201 constituting a process space 205 in which the substrate S is processed, and a transfer chamber 206 provided with a transfer space through which the substrate S passes when being transferred to the process space 205 are provided (formed). The vessel 202 is constituted by an upper vessel 202a and a lower vessel 202b. A partition plate 208 is provided between the upper vessel 202a and the lower vessel 202b.

A loading/unloading port 240 adjacent to a gate valve 241 is provided on a side surface of the lower vessel 202b, and the substrate S is moved between the lower vessel 202b and the second transfer structure 140 through the loading/unloading port 240. A plurality of lift pins 207 are provided on a lower portion of the lower vessel 202b.

A substrate support 210 configured to support the substrate S is arranged in the process space 205. The substrate support 210 includes: a substrate placing table (substrate mounting table) 212 provided with a substrate placing surface 211 on which the substrate S is placed; and a heater 213 serving as a heating structure provided in the substrate placing table 212. The substrate placing table 212 is provided with a plurality of through holes 214 provided at positions corresponding to the lift pins 207, respectively. The lift pins 207 pass through the through holes 214, respectively.

A wiring 222 through which an electric power is supplied is connected to the heater 213. The wiring 222 is connected to a heater controller 223. The heater controller 223 is electrically connected to the controller 400. The controller 400 is configured to control the heater controller 223 to operate (or drive) the heater 213.

The substrate placing table 212 is supported by a shaft 217. The shaft 217 penetrates a lower portion of the vessel 202 and is further connected to an elevator (which is an elevating structure) 218 provided outside the vessel 202.

By operating the elevator 218 to elevate and lower the shaft 217 and the substrate placing table 212, the substrate placing table 212 can elevate and lower the substrate S placed on the substrate placing surface 211.

In addition, the process chamber 201 may be configured with other structures as long as it is possible to secure the process space 205 in which the substrate S is processed.

When the substrate S is transferred, the substrate placing table 212 is lowered to a transfer position P0 where the substrate placing surface 211 faces the loading/unloading port 240, and when the substrate S is processed, the substrate placing table 212 is elevated until the substrate S is at a process position in the process space 205 as shown in FIG. 5.

A lid 231 of the process chamber 201 is provided with a gas introduction hole 231a. A first gas supplier (which is a first gas supply structure) 224, a second gas supplier (which is a second gas supply structure) 225 and an inert gas supplier (which is an inert gas supply structure) 226, which will be described later, are connected to the gas introduction hole 231a. As a result, at least one among a first gas, a second gas and the inert gas can be supplied to the process chamber 201.

Subsequently, an exhauster (which is an exhaust structure) 291 will be described. An exhaust pipe 292 is in communication with the process space 205. That is, the exhaust pipe 292 is connected to the upper vessel 202a so as to be communicated with the process space 205. The exhaust pipe 292 is provided with an APC (Automatic Pressure Controller) valve 293 serving as a pressure regulator (pressure controller) configured to control a pressure (inner pressure) of the process space 205 to a predetermined pressure. The APC valve 293 is provided with a valve structure (not shown) whose opening degree can be adjusted, and is configured to adjust a conductance of the exhaust pipe 292 in accordance with an instruction from the controller 400. A valve 294 is provided at the exhaust pipe 292 at an upstream side of the APC valve 293 in a gas flow direction. A dry pump 295 is provided at a downstream side of the exhaust pipe 292 in the gas flow direction. The dry pump 295 exhausts an atmosphere (inner atmosphere) of the process space 205 through the exhaust pipe 292.

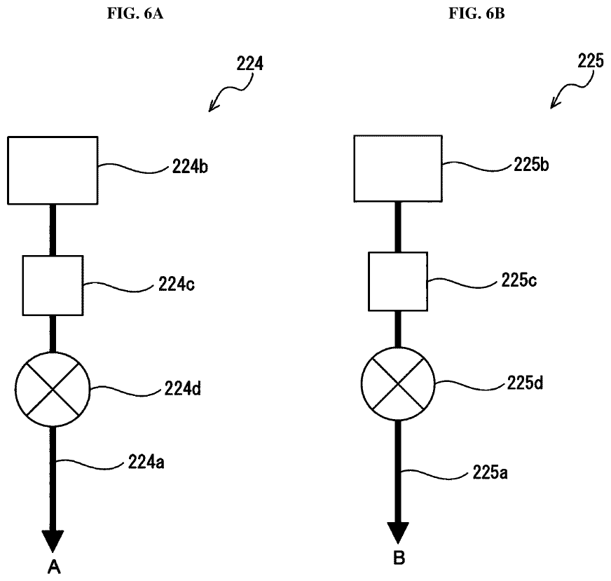

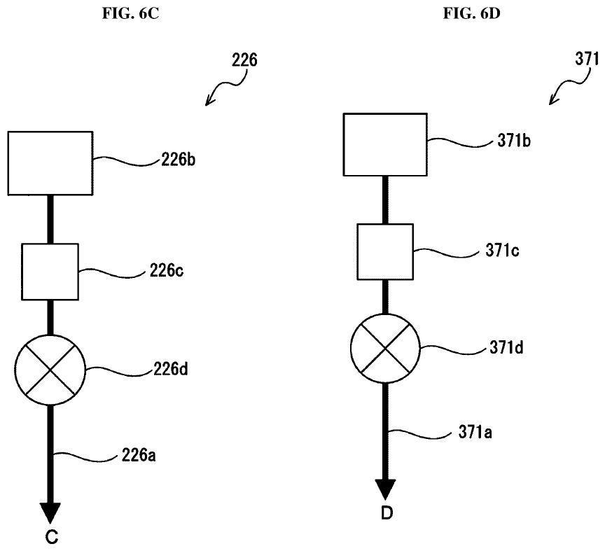

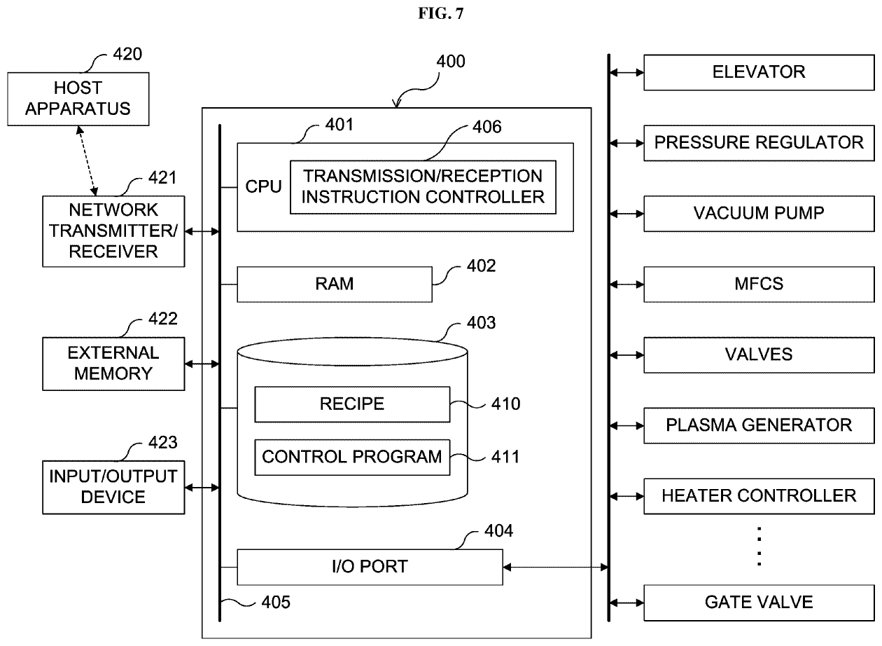

Subsequently, a gas supplier (which is a gas supply structure) capable of supplying a gas through the gas introduction hole 231a to the process chamber 201 will be described with reference to FIGS. 6A, 6B and 6C. In the present disclosure, for example, the first gas supplier 224 and the second gas supplier 225 described in detail below may also be collectively or individually referred to as the “gas supplier”.

First, the first gas supplier 224 capable of supplying the gas (first gas) to the gas introduction hole 231a will be described with reference to FIG. 6A. A first gas source 224b, a mass flow controller (MFC) 224c serving as a flow rate control structure (flow rate controller) and a valve 224d serving as an opening/closing valve are sequentially installed at a gas supply pipe 224a in this order from an upstream side to a downstream side of the gas supply pipe 224a in the gas flow direction.

The first gas source 224b is configured to supply the first gas. The first gas is one of process gases. As the first gas, for example, a gas containing silicon (Si) may be used. As the gas containing silicon (also referred to as a “silicon-containing gas”), for example, hexachlorodisilane (Si₂Cl₆, abbreviated as HCDS) gas may be used.

The first gas supplier (also referred to as a “silicon-containing gas supplier” which is a silicon-containing gas supply structure) 224 is constituted mainly by the gas supply pipe 224a, the MFC 224c and the valve 224d.

Subsequently, the second gas supplier 225 capable of supplying the gas (second gas) to the gas introduction hole 231a will be described with reference to FIG. 6B. A second gas source 225b, a mass flow controller (MFC) 225c and a valve 225d are sequentially installed at a gas supply pipe 225a in this order from an upstream side to a downstream side of the gas supply pipe 225a in the gas flow direction.

The second gas source 225b is configured to supply the second gas. The second gas is one of the process gases. As the second gas, for example, a nitrogen-containing gas may be used. For example, the second gas is a hydrogen nitride-based gas. The second gas may serve as a reactive gas or a modifying gas. As the second gas, for example, ammonia (NH₃) gas may be used.

The second gas supplier (also referred to as a “reactive gas supplier” which is a reactive gas supply structure) 225 is constituted mainly by the gas supply pipe 225a, the MFC 225c and the valve 225d.

Subsequently, the inert gas supplier 226 capable of supplying the gas (inert gas) to the gas introduction hole 231a will be described with reference to FIG. 6C. An inert gas source 226b, an MFC 226c and a valve 226d are sequentially installed at a gas supply pipe 226a in this order from an upstream side to a downstream side of the gas supply pipe 226a in the gas flow direction. For example, the inert gas supplied from the inert gas source 226b may be used as a purge gas for purging an atmosphere (inner atmosphere) of the process chamber 201, or may be used as a pressure adjusting gas for adjusting the inner pressure of the process chamber 201.

### <Intermediate Structure>

As shown in FIG. 2, the intermediate structure 160 is arranged adjacent to the second transfer structure 140 and the reactor 200. In other words, the intermediate structure 160 is provided adjacent to a side surface of the housing 141 of the second transfer structure 140, and is configured to be capable of communicating with the second transfer structure 140 and the reactor 200. In the present embodiment, the intermediate structure 160 is configured to receive the substrate S from the second transfer structure 140 and configured to transfer the substrate S to the reactor 200 in the vacuum atmosphere. In other words, the intermediate structure 160 is a structure in the substrate processing apparatus 100, and is configured such that the substrate S can be transferred between the second transfer structure 140 and the reactor 200.

As shown in FIG. 2, the intermediate structure 160 is arranged between a pair of reactors 200 spaced apart by a distance in the front-rear direction. One of the pair of reactors 200 on one side (front side) of the intermediate structure 160, which may also be referred to as a “front side reactor 200”, may serve as an example of a first processing structure. The other of the pair of reactors 200 on the other side (rear side) of the intermediate structure 160, which may also be referred to as a “rear side reactor 200”, may serve as an example of a second processing structure.

The intermediate structure 160 is provided with a housing 161. The housing 161 is provided with: a first wall 161a adjacent to the front side reactor 200; a second wall 161b adjacent to the rear side reactor 200; a third wall 161c adjacent to the second transfer structure 140; and a fourth wall 161d arranged at a position opposite to the third wall 161c.

The third transfer robot 164 capable of transferring the substrate S is provided in the intermediate structure 160. The third transfer robot 164 is configured to be capable of transferring the substrate S between the second transfer structure 140 and the reactor 200. Specifically, the third transfer robot 164 is configured to receive the substrate S from the second transfer robot 144, and configured to transfer the substrate S to the substrate placing table 212 in the reactor 200. In other words, the substrate S is placed on the substrate placing table 212.

At the housing 161 of the intermediate structure 160, a supply pipe 167 through which the inert gas is supplied into the housing 161 and an exhauster (which is an exhaust structure) 168 through which an atmosphere (inner atmosphere) of the housing 161 is exhausted are provided. An inert gas supplier (which is an inert gas supply structure) 371 shown in FIG. 6D is connected to the supply pipe 167.

The inert gas supplier 371 is provided with a gas supply pipe 371a. An inert gas source 371b, an MFC 371c and a valve 371d are sequentially installed at the gas supply pipe 371a in this order from an upstream side to a downstream side of the gas supply pipe 371a in the gas flow direction. For example, the inert gas supplied from the inert gas source 371b may be used as the purge gas for purging an atmosphere (inner atmosphere) of the intermediate structure 160. The inert gas supplier 371 may also be referred to as a “third gas supplier” which is a third gas supply structure.

The exhauster 168 is provided with an exhaust pipe 168a communicating with an inside of the housing 161. A pump (not shown) serving as an exhaust apparatus is connected to the exhaust pipe 168a through a valve 168b serving as an opening/closing valve and an APC valve 168c. The pump is configured to exhaust the inner atmosphere of the housing 161 such that a pressure (inner pressure) of the housing 161 can be adjusted to a predetermined pressure. In addition, the intermediate structure 160 may be configured such that the inner atmosphere of the intermediate structure 160 can return from the vacuum atmosphere to the atmospheric atmosphere while the third transfer robot 164 is supporting the processed substrate S for which a processing is completed in the reactor 200.

Each of second loading/unloading ports 163 provided on the first wall 161a and the second wall 161b is arranged at a lateral position with respect to an entrance direction of the substrate S loaded through a first loading/unloading port 162 provided on the third wall 161c. Hereinafter, each of the second loading/unloading ports 163 may also be referred to as a “second loading/unloading port 163”.

An arm 164a included in the third transfer robot 164 may be configured such that its rotation within a space surrounded by the first wall 161a, the second wall 161b and the third wall 161c is allowed (or permitted) but its rotation in a direction from the first wall 161a or the second wall 161b toward the fourth wall 161d is prevented. That is, the arm 164a of the third transfer robot 164 is prevented from rotating from the first wall 161a and the second wall 161b toward the fourth wall 161d. Specifically, the arm 164a of the third transfer robot 164 (that is, the intermediate transfer robot) can rotate in a first range surrounded by the first wall 161a, the second wall 161b and third wall 161c, and its rotation is restricted in a second range extending from the first wall 161a and the second wall 161b toward the fourth wall 161d. In other words, a space between the third transfer robot 164 and the fourth wall 161d may be set to be narrower than other spaces, specifically, a space between the third transfer robot 164 and the first wall 161a, a space between the third transfer robot 164 and the second wall 161b and a space between the third transfer robot 164 and the third wall 161c.

In addition, according to the present embodiment, as shown in FIG. 2, a plurality of combinations of the intermediate structure 160 and the reactors 200 may be arranged along the side surfaces of the housing 141 which constitutes the second transfer structure 140.

In addition, the combinations of the front side reactor 200, the rear side reactor 200 and the intermediate structure 160 between the front side reactor 200 and the rear side reactor 200 may be arranged so as to be point symmetrical at positions facing one another with the second transfer structure 140 interposed therebetween.

Each of the combinations of the intermediate structure 160 and the reactors 200 is arranged along the side surfaces of the housing 141. Further, in locations where two combinations are adjacent to each other, for example, the positions of the front side reactor 200 and the rear side reactor 200 in each of the two combinations are set such that the reactor 200 (such as the rear side reactor 200) of one combination is adjacent to the reactor 200 (such as the front side reactor 200) of the other combination.

In addition, according to the present embodiment, the unprocessed substrate S is transferred from the second transfer robot 144 to the third transfer robot 164. Then, the processed substrate S is transferred from the third transfer robot 164 to the second transfer robot 144.

### <Controller>

Subsequently, the controller 400 will be described using FIG. 7. The substrate processing apparatus 100 includes the controller 400 configured to control operations of components constituting the substrate processing apparatus 100.

For example, the controller 400 is constituted by a computer including a CPU (Central Processing Unit) 401, a RAM (Random Access Memory) 402, a memory 403 and an I/O port (input/output port) 404. The RAM 402, the memory 403 and the I/O port 404 are configured to be capable of exchanging data with the CPU 401 via an internal bus 405. The transmission/reception of the data in the substrate processing apparatus 100 may be performed by an instruction from a transmission/reception instruction controller 406 which is one of functions of the CPU 401.

The CPU 401 is configured to read and execute the control program from the memory 403, and is configured to read a process recipe from the memory 403 in accordance with an instruction such as an operation command inputted from an input/output device 423. For example, in accordance with contents of the process recipe from the memory 403, the CPU 401 is further configured to be capable of controlling various operations such as an elevating and lowering operation of each elevator, a substrate transfer operation by each robot, an on/off control of each pump, a flow rate adjusting operation of each MFC, and an opening and closing operation of each valve.

For example, the memory 403 may be embodied by a component such as a flash memory and an HDD (Hard Disk Drive). For example, a recipe 410 (which is constituted by the process recipe in which procedures and conditions of a substrate processing are written) and a control program 411 (which is configured to control the operations of the substrate processing apparatus 100) may be readably stored in the memory 403.

In addition, the process recipe is obtained by combining procedures (steps) of the substrate processing described later, and acts as a program that is executed by the controller 400 to obtain a predetermined result by performing the steps of the substrate processing described later. For example, the process recipe may exist for each reactor, and is read out for each reactor.

Hereinafter, the process recipe and the control program may be collectively or individually referred to simply as a “program.” Thus, in the present specification, the term “program” may refer to the process recipe alone, may refer to the control program alone, or may refer to both of the process recipe and the control program. The RAM 402 serves as a memory area (work area) in which the program or the data read by the CPU 401 is temporarily stored.

The I/O port 404 is electrically connected to the components such as each pressure regulator, each pump and the heater controller. In addition, In addition, a network transmitter/receiver 421 connected to a host apparatus 420 via a network is provided.

For example, the controller 400 according to the present disclosure may be embodied by preparing an external memory 422 storing the program described above and by installing the program onto the computer by using the external memory 422. As the external memory 422, for example, a magnetic disk such as a hard disk, an optical disk such as a DVD, a magneto-optical disk such as an MO, a semiconductor memory such as a USB memory may be used. Further, a method of providing the program to the computer is not limited to such a method using the external memory 422. For example, the program may be directly provided to the computer by a communication interface such as the Internet and a dedicated line instead of the external memory 422. Further, the memory 403 and the external memory 422 may be embodied by a non-transitory computer-readable recording medium. Hereinafter, the memory 403 and the external memory 422 may be collectively or individually referred to as a “recording medium”. Thus, in the present specification, the term “recording medium” may refer to the memory 403 alone, may refer to the external memory 422 alone, or may refer to both of the memory 403 and the external memory 422.

### (2) Substrate Processing

Subsequently, the substrate processing will be described with reference to FIGS. 1 to 5. As a part of steps performed by the substrate processing apparatus 100, a step of processing the substrate S using the substrate processing apparatus 100 whose configuration is mentioned above will be described. Further, in the following description, the controller 400 controls the operations of the components constituting the substrate processing apparatus 100.

### <Substrate Transfer Step>

A first transfer step will be described.

First, as shown in FIGS. 1 and 2, the substrate processing apparatus 100 receives (or takes out) the substrate S from the storage container 102 supported on the support table 111 of the loading port structure 110 using the first transfer robot 124 of the first transfer structure 120.

Subsequently, the substrate processing apparatus 100 transfers the substrate S contained in the storage container 102 from the first transfer structure 120 via the second transfer structure 140 to the intermediate structure 160 to which the substrate S is to be transferred. Specifically, as shown in FIGS. 2 and 4, the substrate S is transported toward the second transfer robot 144 in charge of the intermediate structure 160 to which the substrate S is to be transferred, and the second transfer robot 144 transfers the substrate S to the intermediate structure 160.

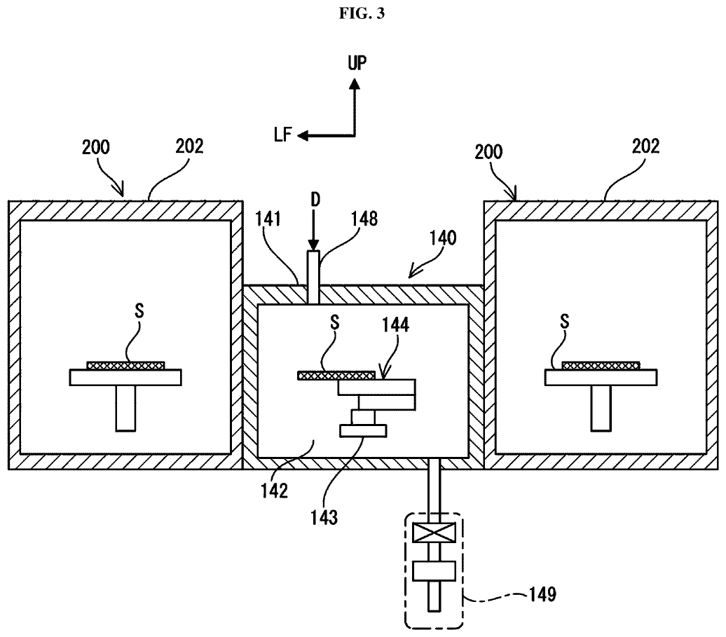

For example, when the front side second transfer robot 144a is in charge of the reactor 200 to which the substrate S is to be transferred, the first transfer robot 124 is used to take out the substrate S from the storage container 102. Then, the front side second transfer robot 144a takes out the substrate S from the storage container 102 and transfers the substrate S to the intermediate structure 160 to which the substrate S is to be transferred. Thereafter, the front side second transfer robot 144a transports the substrate S to the third transfer robot 164 in the intermediate structure 160 to which the substrate S is to be transferred. Subsequently, the third transfer robot 164 transports the substrate S to the reactor 200 (see FIG. 3). In other words, when the front side second transfer robot 144a is in charge of the intermediate structure 160 to which the substrate S is to be transferred, the substrate S is transferred to the intermediate structure 160 to which the substrate S is to be transferred through the first transfer structure 120 and the second transfer structure 140.

### <Substrate Loading Step>

Subsequently, a substrate loading step will be described. In the substrate loading step, the substrate placing table 212 supporting the substrate S is elevated and loaded into the process chamber 201 as shown in FIG. 5. The heater 213 is in operation such that a temperature (inner temperature) of the process chamber 201 is maintained at a process temperature of the substrate S.

Then, by co-operation of the inert gas supplier 226 and the exhauster 291, a pressure (inner pressure) of the process chamber 201 is set (or adjusted) to a predetermined pressure.

### <Film Processing Step>

Subsequently, a film processing step will be described. The film processing step is a step of processing a film formed on the substrate S in the reactor 200. When the inner pressure of the process chamber 201 reaches and is maintained at a desired pressure, the first gas supplier 224 and the second gas supplier 225 are controlled to supply the first gas and the second gas into the process chamber 201 to process the substrate S. For example, a processing in the present step may refer to a process of forming a predetermined film on the substrate S by reacting the first gas with the second gas. According to the present embodiment, for example, by supplying the HCDS gas as the first gas and supplying the NH₃ gas as the second gas, it is possible to form a silicon nitride film (SiN film).

After a predetermined time has elapsed, the first gas supplier 224 and the second gas supplier 225 are stopped. In addition, by supplying the inert gas through the inert gas supplier 226, it is possible to exhaust the inner atmosphere of the process chamber 201.

### <Substrate Unloading Step>

A substrate unloading step will be described. After a predetermined time has elapsed, the substrate placing table 212 is lowered. After the substrate placing table 212 is lowered, the substrate S is unloaded in a manner reverse to that of loading the substrate S.

In the substrate processing apparatus 100 of the present embodiment, an entirety of the reactors 200 are used to form the film. However, the technique of the present disclosure is not limited thereto. For example, one of the reactors 200 may be dedicated to a cooling operation of the substrate. That is, the substrate processing apparatus 100 may include a cooling structure (cooling module) in at least one among the reactors 200. In addition, the cooling structure may be provided with a temperature sensor capable of monitoring a temperature of the substrate S. By providing the cooling structure in at least one among the reactors 200 and cooling the processed substrate S with the cooling structure, it is possible to alleviate a congestion in the processing of the substrate S. As a result, it is possible to improve an overall processing efficiency of the apparatus (that is, the substrate processing apparatus 100).

Subsequently, actions and effects according to the present embodiment will be described. In the substrate processing apparatus 100 according to the present embodiment, by arranging the plurality of reactors 200 and the plurality of intermediate structures 160 along the second transfer structure 140 configured to transfer the substrate S in the atmospheric atmosphere, it is possible to minimize a transfer distance of the substrate S. As a result, it is possible to improve a productivity of the substrate processing. In addition, by configuring the substrate processing apparatus 100 to be vertically long, it is possible to reduce an installation width of the apparatus. In addition, in the substrate processing apparatus 100, the substrate S is transferred to the reactor 200 from the intermediate structure 160 which is in the vacuum atmosphere. Thereby, the substrate S is less susceptible to effects of particles during the processing in the reactor 200.

In the substrate processing apparatus 100, the third transfer robot 164 is provided in the intermediate structure 160. Thereby, it is possible to reduce the installation width of the apparatus as compared with a configuration, for example, in which a vacuum transfer robot is provided in a room separate from the intermediate structure.

In the substrate processing apparatus 100, the arm 164a of the third transfer robot 164 is prevented from rotating in a direction from the first wall 161a and the second wall 161b toward the fourth wall 161d. As a result, it is possible to shorten a distance between the third transfer robot 164 and the fourth wall 161d. In other words, in the substrate processing apparatus 100, it is possible to reduce a volume of the intermediate structure 160 as compared with a configuration in which a rotation of the arm 164a within a space surrounded by the first wall 161a, the second wall 161b, the third wall 161c and the fourth wall 161d is allowed. As a result, it is possible to reduce a footprint of the apparatus.

In the substrate processing apparatus 100, when the inner atmosphere of the intermediate structure 160 returns from the vacuum atmosphere to the atmospheric atmosphere while the third transfer robot 164 is supporting the processed substrate S, by supplying the gas through the second transfer structure 140 into the intermediate structure 160, it is possible to cool the substrate S. Therefore, in the substrate processing apparatus 100, since the substrate S can be cooled without providing an independent cooling structure in the intermediate structure 160, it is possible to increase a transfer efficiency of the processed substrate S. As a result, it is possible to improve a throughput of the substrate processing apparatus 100.

In the substrate processing apparatus 100, the second loading/unloading ports 163 are arranged at lateral positions with respect to the entrance direction of the substrate S loaded through the first loading/unloading port 162. As a result, it is possible to distribute the substrate S in a space-saving manner with a short throughput.

In the substrate processing apparatus 100, the intermediate structure 160 and the reactor 200 can be added in pairs. As a result, it is possible to easily change a design of the substrate processing apparatus 100 since it is unnecessary to redesign the substrate processing apparatus 100 every time the intermediate structure 160 and the reactor 200 are added.

In the substrate processing apparatus 100, since the intermediate structure 160 is arranged between the reactors 200, it is possible to set the distances from the intermediate structure 160 to the reactors 200 substantially the same. As a result, it is possible to easily set a transfer schedule of the substrate S.

In the substrate processing apparatus 100, the combinations of the front side reactor 200, the rear side reactor 200 and the intermediate structure 160 between the front side reactor 200 and the rear side reactor 200 are arranged so as to be point symmetrical at positions facing one another with the second transfer structure 140 interposed therebetween. Therefore, the front side reactor 200, the rear side reactor 200 and the intermediate structure 160, which are common components, can be used. As a result, it is possible to reduce an overall cost of the apparatus.

In the substrate processing apparatus 100, it is possible to transfer the substrate S directly between the second transfer robot 144 and the third transfer robot 164. As a result, it is possible to improve the transfer efficiency of the substrate S.

### Second Embodiment

Subsequently, a substrate processing apparatus 500 according to a second embodiment of the present disclosure will be described. In the substrate processing apparatus 500 according to the present embodiment, the reactors 200 are replaced with reactors 300. That is, a configuration of the substrate processing apparatus 500 is substantially the same as that of the substrate processing apparatus 100 according to the first embodiment, except for configurations of the reactors 300 and the intermediate structures 160. Therefore, according to the present embodiment, the configurations of the reactors 300 and the intermediate structures 160 will be described. Descriptions of components of the substrate processing apparatus 500 similar to those of the substrate processing apparatus 100 according to the first embodiment will be omitted.

### <Reactor: Batch Type Apparatus>

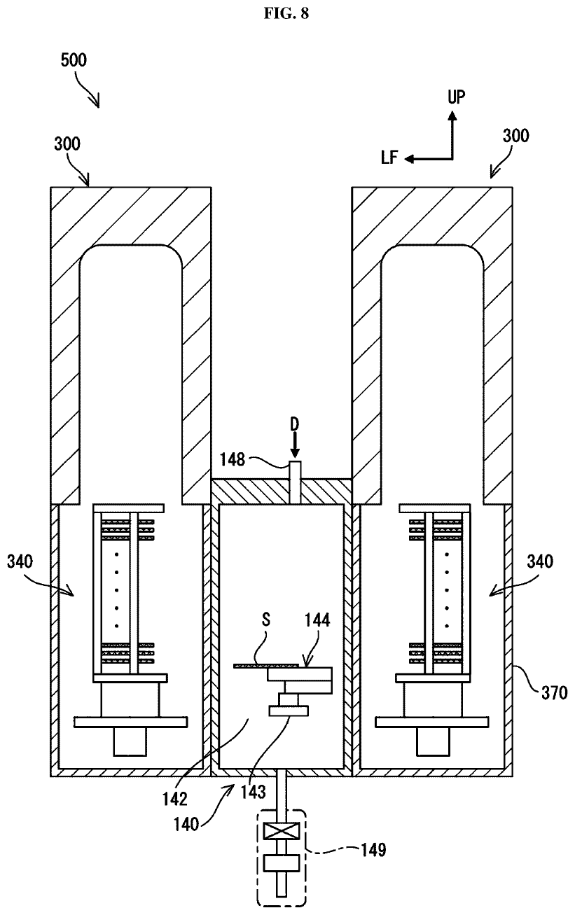

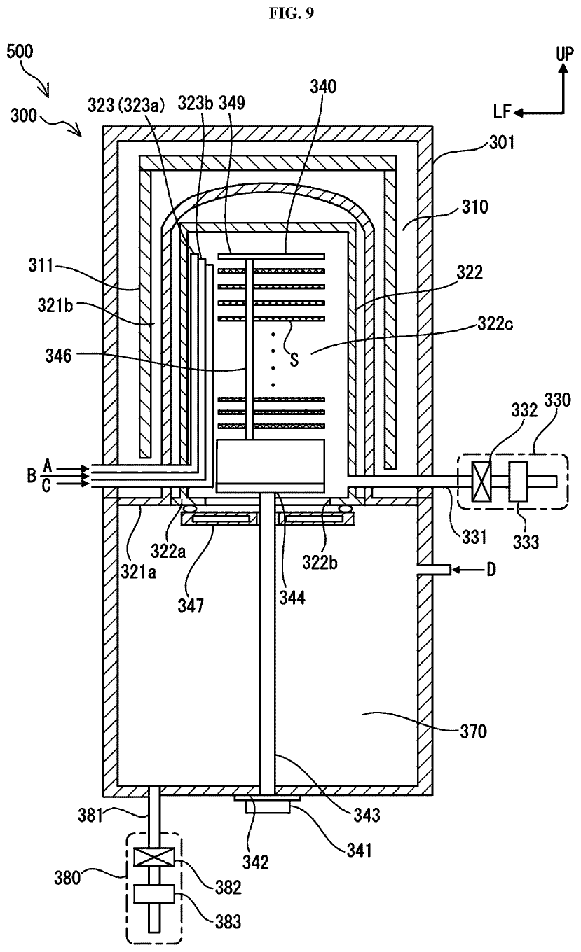

FIG. 8 is a diagram illustrating a vertical cross-section taken along the line β-β in FIG. 1. As shown in FIGS. 8 and 9, the plurality of reactors 300 are arranged on both sides of the width direction of the second transfer structure 140. Hereinafter, each of the reactors 300 may also be referred to as a “reactor 300”. The reactor 300 serves as a module (structure) capable of processing the substrate S in the storage container 102. Since configurations of the reactors 300 are substantially the same, the reactor 300 will be described as a representative example. Each of the reactors 300 is configured to be capable of processing the plurality of substrates S. The reactor 300 will be described in detail below.

As shown in FIG. 9, a housing 301 constituting the reactor 300 is provided with a reaction tube storage chamber 310 at an upper portion thereof and a transfer chamber 370 at a lower portion thereof. In the reaction tube storage chamber 310, a heater 311 and a reaction tube 322 are mainly stored (accommodated). The transfer chamber 370 is provided adjacent to the inside of the housing 161 of the intermediate structure 160, and is in communication with the inside of the housing 161 through the second loading/unloading port 163. The third transfer robot 164 transfers the substrate S to a substrate support 340 described later, or receives the substrate S from the substrate support 340.

The transfer chamber 370 is installed at a lower portion of the reaction tube 322, and is configured to communicate with the reaction tube 322.

Subsequently, the reaction tube storage chamber 310 and the reaction tube 322 accommodated therein will be described. The reaction tube 322 is accommodated inside the reaction tube storage chamber 310.

The upper portion of the reaction tube 322 is closed, and a furnace opening structure 322b is provided at the lower portion of the reaction tube 322. A hole through which the substrate support 340 passes is provided at a center of the furnace opening structure 322b.

The reaction tube 322 is configured to be capable of accommodating the plurality of substrates S supported by the substrate support 340. A nozzle 323 serving as a part of a gas supplier (gas supply structure) is provided at the reaction tube 322. The nozzle 323 is configured to extend in a vertical direction, which is an arrangement direction of the substrates S. The gas supplied through the nozzle 323 is supplied to each of the substrates S.

For example, a plurality of nozzles including the nozzle 323 are provided for each type of gases. According to the present embodiment, for example, three nozzles 323a, 323b and 323c are provided. Hereinafter, the plurality of nozzles including the nozzle 323 may also be collectively referred to as “nozzles 323”. The nozzles 323 are arranged so as not to overlap one another in the horizontal direction. For example, the nozzles 323 are connected to the first gas supplier 224, the second gas supplier 225 and the inert gas supplier 226, respectively. In addition, for convenience of explanation, three nozzles 323 are shown in FIG. 9. However, the present embodiment is not limited thereto. For example, as the nozzles 323, four or more nozzles or two or less nozzles may be arranged in accordance with contents of the substrate processing.

According to the present embodiment, it is possible to obtain substantially the same actions and effects as in the first embodiment mentioned above.

An exhauster (exhaust structure) 330 configured to exhaust an atmosphere (inner atmosphere) of the reaction tube 322 is provided with an exhaust pipe 331 communicating with the reaction tube 322.

A pump (not shown) serving as an exhaust apparatus is connected to the exhaust pipe 331 through a valve 332 serving as an opening/closing valve and an APC valve 333. The pump is configured to exhaust the inner atmosphere of the reaction tube 322 such that a pressure (inner pressure) of the reaction tube 322 can be adjusted to a predetermined pressure. For example, the term “predetermined pressure” is the same level of a pressure as a pressure (inner pressure) of the transfer chamber 370.

By co-operation of the gas supplier and the exhauster, the inner pressure of the reaction tube 322 is adjusted. When adjusting the inner pressure of the reaction tube 322, a pressure value detected by a pressure detector (not shown) is adjusted to a predetermined value.

An area (region) of the reaction tube 322 where the substrate S is accommodated may also be referred to as a “process area” or a “process region”, and a structure constituting the process area may also be referred to as a “process chamber 322c”. According to the present embodiment, the process chamber 322c is constituted by the reaction tube 322.

In the transfer chamber 370, the substrates S are transferred to the substrate support 340 through the second loading/unloading port 163 by the third transfer robot 164. In addition, the substrate support 340 transfers the substrates S (which are transferred by the third transfer robot 164) into the reaction tube 322. Then, in the reaction tube 322, a process such as a process of forming a film on a surface of the substrate S is performed.

The substrate support 340 is provided with an elevator (elevating structure) 341 capable of driving the substrate support 340 in the vertical direction. In FIG. 9, a state where the substrate support 340 is elevated by the elevator 341 and accommodated in the reaction tube 322 is shown. In addition, the substrate support 340 is further provided with a rotation driver (which is a rotation driving structure) 342 capable of driving the substrate support 340 to rotate.

Each driver is connected to a shaft 343 configured to support a support table 344. The support table 344 is provided with a plurality of support columns 346 capable of supporting the substrates S. Each of the support columns 346 is provided with a plurality of substrate support structures with a predetermined interval therebetween in the vertical direction, and the substrates S are supported by the plurality of substrate support structures, respectively.

The substrate support 340 supports a desired number of substrates S, for example, from 3 substrates to 50 substrates, in a multistage manner in the vertical direction by using the plurality of support columns 346.

The substrate support 340 is moved in the up-down direction between the reaction tube 322 and the transfer chamber 370 by the elevator 341. In addition, for example, when processing the substrate S, the substrate support 340 is rotated around a center of the substrate S serving as an axis by the rotation driver 342.

A lid 347 configured to close the furnace opening structure 322b is fixed to the shaft 343. A diameter of the lid 347 is set to be larger than a diameter of the furnace opening structure 322b.

For example, while processing the substrate S, the lid 347 closes the furnace opening structure 322b. When the lid 347 closes the furnace opening structure 322b, the elevator 341 elevates the lid 347 such that the lid 347 is set to a position where an upper surface of the lid 347 is pressed against a flange 322a, as shown in FIG. 9. As a result, it is possible to maintain the inside of the reaction tube 322 airtight.

The transfer chamber 370 is installed below the reaction tube storage chamber 310. In the transfer chamber 370, the second transfer robot 144 places (mounts) the substrate S on the substrate support 340 through a loading/unloading port related thereto, and the second transfer robot 144 takes out the substrate S from the substrate support 340.

At the transfer chamber 370, an exhauster (which is an exhaust structure) 380 through which an atmosphere (inner atmosphere) of the transfer chamber 370 is exhausted is provided. The exhauster 380 is connected to the transfer chamber 370 and, is provided with an exhaust pipe 381 communicating with an inside of the transfer chamber 370.

A vacuum pump (not shown) serving as a vacuum exhaust apparatus is connected to the exhaust pipe 381 through a valve 382 serving as an opening/closing valve and an APC valve 383. The vacuum pump is configured to exhaust the inner atmosphere of the transfer chamber 370 such that the inner pressure of the transfer chamber 370 can be adjusted to a predetermined pressure.

The inert gas supplier 371 shown in FIG. 6D may be connected to the transfer chamber 370. The inert gas supplied from the inert gas source 371b is used, for example, to purge the inner atmosphere of the transfer chamber 370 or to adjust the inner pressure of the transfer chamber 370.

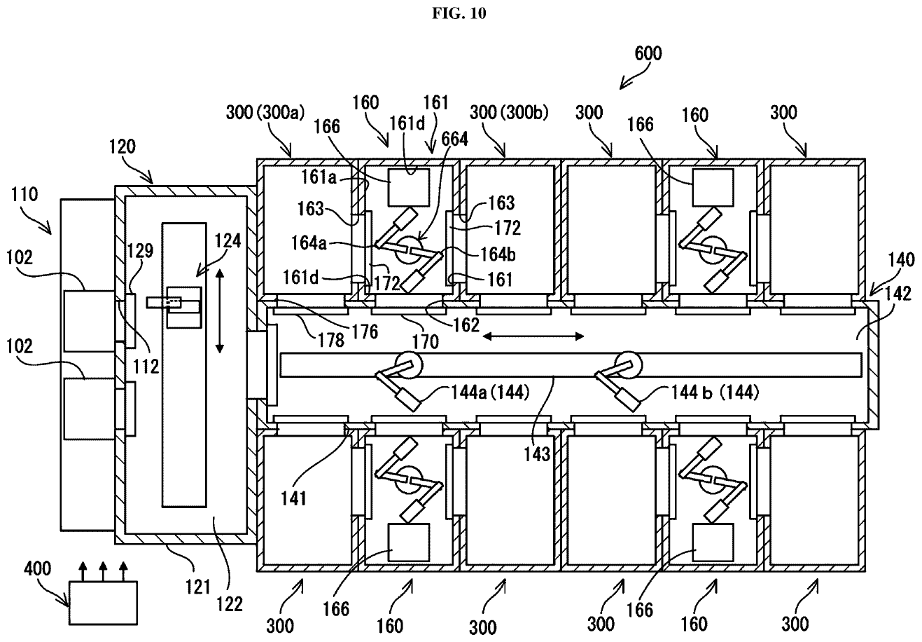

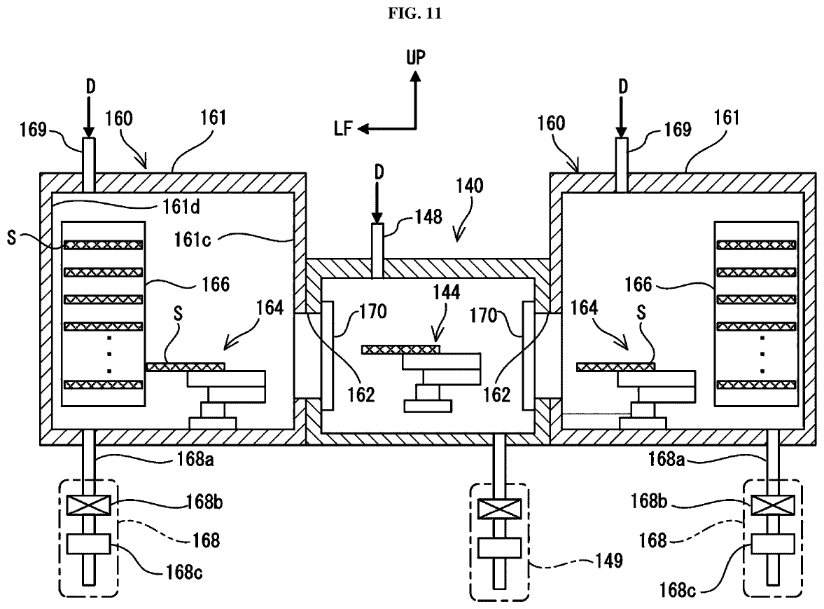

Subsequently, the intermediate structure 160 according to the present embodiment will be described. As shown in FIGS. 10 and 11, a standby structure 166 in which the substrate S is in standby may be provided in the intermediate structure 160. Specifically, it is preferable that the standby structure 166 is capable of supporting the substrates S. In a manner mentioned above, when the standby structure 166 is provided in the substrate processing apparatus 500, even when a timing of unloading the substrate S from the reactor 300 to the intermediate structure 160 and a timing of loading the substrate S from the second transfer structure 140 to the intermediate structure 160 do not match, the substrate S or the substrates S transferred from either one of the reactor 300 and the second transfer structure 140 can be in standby in the standby structure 166. As a result, it is possible to maintain the transfer efficiency of the substrate S.

In addition, the standby structure 166 may be configured such that the substrates S can be stacked therein, and the standby structure 166 and the third transfer robot 164 may be configured to be capable of being moved relatively in the up-down direction. In such a case, in the substrate processing apparatus 500, by configuring the standby structure 166 and the third transfer robot 164 so as to be capable of being moved relatively in the up-down direction, it is possible to efficiently transfer the substrate S between the standby structure 166 and the third transfer robot 164.

In addition, the controller 400 may also perform a control such that the substrate S is transferred to the standby structure 166 when the number of substrates S capable of being supported by the substrate support 340 is greater than the number of substrates S capable of being transferred by the third transfer robot 164. In such a case, in the substrate processing apparatus 500, the substrate S is transferred to the standby structure 166. Therefore, for example, as compared with a configuration in which the substrate S is not transferred to the standby structure 166, it is possible to adjust a speed limit of the third transfer robot 164. As a result, it is possible to improve the transfer efficiency of the substrate S.

In addition, the intermediate structure 160 may further include a cooling structure 169 capable of cooling the processed substrate S for which the processing is completed in the reactor 300. In the substrate processing apparatus 500, the processed substrate S whose temperature is increased due to the processing in the reactor 300 can be cooled by the cooling structure 169 of the intermediate structure 160. As a result, it is possible to improve the transfer efficiency of the substrate S.

In addition, by supplying the inert gas to the processed substrate S, moisture around the substrate S can be removed. As a result, it is possible to suppress a reaction by the moisture in the atmosphere and it is also possible to prevent an undesired modification of the film. In addition, by cooling the processed substrate S, it is possible to lower the temperature of the substrate S to a heat resistant temperature of the second transfer robot 144.

Subsequently, operations of the substrate processing apparatus 500 will be described. When a gate valve 170 is opened, the substrate S is transferred between the second transfer robot 144 and the third transfer robot 164. The substrate S received by the third transfer robot 164 is transferred to the standby structure 166. After a predetermined number of substrates S are transferred to the standby structure 166, the gate valve 170 is closed, and then the inner atmosphere of the housing 161 is exhausted by the exhaust structure 380.

When the inner pressure of the housing 161 reaches a desired pressure, a gate valve 172 is opened, and the third transfer robot 164 moves the substrates S from the standby structure 166 to the substrate support 340. After a desired number of substrates S are transferred to the substrate support 340, the gate valve 172 is closed. Thereafter, with the heater 311 in operation, the substrate support 340 is transferred into the reaction tube 322, and the substrates S are processed.

When the processing of the substrate S is completed, the substrate support 340 is unloaded from the reaction tube 322 by performing operations in a manner reverse to those of loading the substrate support 340. In the intermediate structure 160, the third transfer robot 164 transfers the substrate S to the standby structure 166. In the intermediate structure 160, the inert gas is supplied from the cooling structure 169 into the housing 161 to cool the substrate S which is in a high temperature state.

After cooling the substrate S, the inner atmosphere of the housing 161 is adjusted such that the substrate S can be moved into the housing 141. When the desired pressure is reached, the substrate S is transferred between the third transfer robot 164 and the second transfer robot 144.

With such a configuration described above, it is possible to process a large number of substrates S while achieving substantially the same effects as in the first embodiment. In addition, in the substrate processing apparatus 500, it is possible to set an atmosphere (inner atmosphere) of the reactor 300 and the inner atmosphere of the intermediate structure 160 as independent atmospheres. Therefore, even when the inner atmosphere of the intermediate structure 160 is switched between a vacuum level (vacuum atmosphere) and an atmospheric level (atmospheric atmosphere), the reactor 300 is not affected. As a result, for example, the reactor 300 can be made of quartz whose strength is weaker than a metal material.

### Third Embodiment

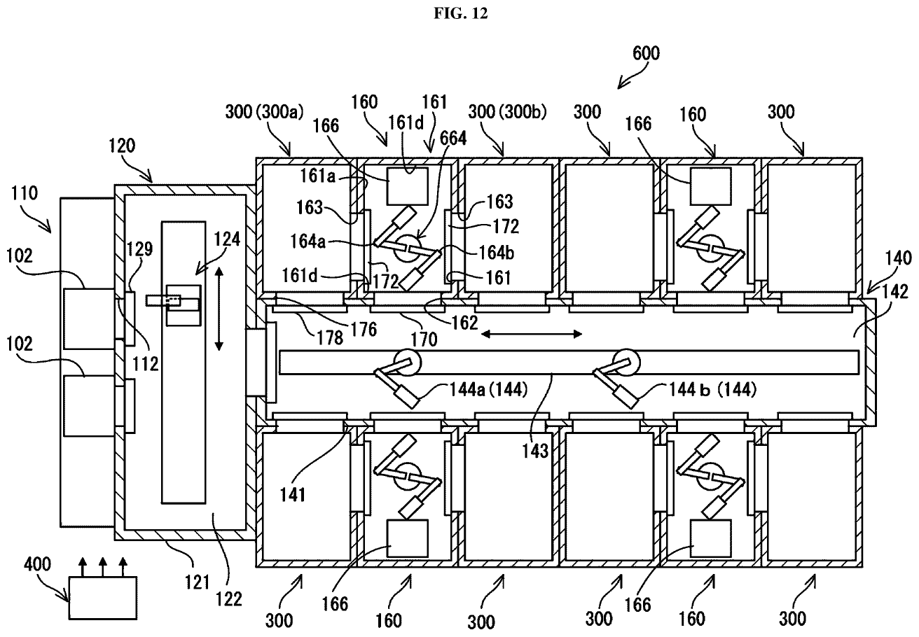

Subsequently, a substrate processing apparatus 600 according to a third embodiment of the present disclosure will be described. As shown in FIG. 12, each of the reactors 300 included in the substrate processing apparatus 600 of the present embodiment is provided with a loading/unloading port 176 communicating with the second transfer structure 140. A gate valve 178 is attached to the loading/unloading port 176. In addition, a third transfer robot 664 included in the substrate processing apparatus 600 of the present embodiment is provided with a pair of arms 164a and 164b. The pair of arms 164a and 164b of the third transfer robot 664 are independently controlled by the controller 400.

In the two reactors 200 provided adjacent to the intermediate structure 160, different types of the substrate processing can be performed. For example, in a reactor 300a, the HCDS gas and the NH₃ gas are supplied to the substrate S to perform a film forming process (also referred to as a “first film process”) of forming the silicon nitride film on the substrate S, and in a reactor 300b, hydrogen (H₂) gas is supplied to the silicon nitride film formed in the reactor 300a to perform a modification process (also referred to as a “second film process”).

In addition, a configuration of the substrate processing apparatus 600 is substantially the same as that of the substrate processing apparatus 500 according to the second embodiment, except for configurations of the loading/unloading port 176, the gate valve 178 and the third transfer robot 664. Therefore, according to the present embodiment, an example of operations of transferring the substrate S and processing the substrate when the third transfer robot 664 is used will be described. In addition, descriptions of components of the substrate processing apparatus 600 similar to those of the substrate processing apparatus 500 according to the second embodiment will be omitted.

Subsequently, operations of the present embodiment will be described. First, the inner pressure of the transfer chamber 370 and a pressure (inner pressure) of the intermediate structure 160 are set to the same pressure. In addition, the inner pressure of the transfer chamber 370 and the inner pressure of the intermediate structure 160 are set to a pressure lower than that of the second transfer structure 140. At this time, the second transfer robot 144 (specifically, the front side second transfer robot 144a) is in a state where the substrate S is supported (held) thereon.

When the inner pressure of the transfer chamber 370 adjacent to the reactor 300a is adjusted to the same level as that of the transfer space 142 (for example, an atmospheric transfer level), the gate valve 178 is opened. Hereinafter, the transfer chamber 370 adjacent to (or related to) the reactor 300a may also be simply referred to as the “transfer chamber 370”. The same also applies to other components of the present embodiment. Then, the substrate S is supported by the substrate support 340 in the reactor 300a by the second transfer robot 144. After an operation of supporting the substrate S is completed, the gate valve 178 is closed.

After adjusting the inner atmosphere of the transfer chamber 370 adjacent to the reactor 300a, the substrate support 340 is moved (loaded) into the reaction tube 322 (process chamber 322c) of the reactor 300a to process the substrate S. When the substrate S is processed, the HCDS gas and the NH₃ gas are supplied to the substrate S to form the silicon nitride film on the substrate S.

After processing the substrate S in the reactor 300a, the substrate support 340 is moved (unloaded) from the reaction tube 322 to the transfer chamber 370. After adjusting the inner pressure of the intermediate structure 160 to the same pressure level as that of the transfer chamber 370 of the reactor 300a, the gate valve 172 is opened. At this time, the inner pressure of the transfer chamber 370 of the reactor 300b is also adjusted to the same pressure level.

The arm 164a of the third transfer robot 164 picks up the substrate S from the substrate support 340 of the reactor 300a and transfers the substrate S to the standby structure 166. At this time, when another substrate (which is processed in the reactor 300a) among the substrates S is already present in the standby structure 166, the gate valve 172 adjacent to the reactor 300b is opened before opening the gate valve 172 adjacent to the reactor 300a, and the arm 164b moves the another substrate to the substrate support 340 of the reactor 300b.

In the intermediate structure 160, when a predetermined number of substrates S are transferred from the reactor 300a to the standby structure 166 and the gate valves 170 and 172 are closed, the inert gas is supplied to start cooling the substrates S. By cooling the substrate S, even when the inner atmosphere of the intermediate structure 160 contains an oxygen component, a reaction between the film formed on the substrate S and the oxygen component can be suppressed. As a result, it is possible to suppress an unexpected oxidation of the substrate S. Therefore, it is possible to maintain a quality of the film formed on the substrate S.

In addition, such a cooling process is effective when a subsequent process is to be performed in the reactor 300b and the effect of the oxygen component is undesirable. By suppressing the oxidation of the film in the intermediate structure 160, the substrate S is not oxidized before being transferred to the reactor 300b. As a result, it is possible to achieve a desired quality of the processing in the reactor 300b.

After the cooling process of the substrate S in the intermediate structure 160 is completed, the gate valve 172 adjacent to the reactor 300b is opened, and the arm 164b moves the substrate S to the substrate support 340 of the reactor 300b.

When the reactor 300b is set to perform the first film process alone without performing the second film process, the gate valve 170 may be opened before opening the gate valve 172, and the substrate S may be transferred from the intermediate structure 160 to the transfer space such that the arm 164b transfers the substrate S to the second transfer robot 144.

When the gate valve 172 adjacent to the reactor 300b is closed, the substrate support 340 is moved into the reaction tube 322 (that is, into the process chamber 322c) in the reactor 300b to process the substrate S. In the reaction tube 322, the H₂ gas is supplied to the substrate S to modify the film formed on the substrate S.

After the processing in the reactor 300b is completed, the substrate S is moved to the transfer chamber 370 of the reactor 300b.

When it is confirmed that the inner pressures of the transfer space 142 and the inner pressure of the transfer chamber 370 are the same, the gate valve 178 adjacent to the reactor 300b is opened. Then, the second transfer robot 144 unloads (transfers) the substrate S processed in the reactor 300b.

In a manner mentioned above, the transfer of the substrate S and the substrate processing when the third transfer robot 664 is used are performed.

The controller 400 performs a control such that the unprocessed substrate S in the transfer space 142 is transferred into the reactor 300a, the processed substrate S for which the processing is completed in the reactor 300a is moved to the intermediate structure 160, the processed substrate S is transferred from the intermediate structure 160 into the reactor 300b, and then the processed substrate S is transferred from the reactor 300b to the transfer space 142. In the substrate processing apparatus 600, by using separate transfer routes for the unprocessed substrate S and the processed substrate S, it is possible to improve the transfer efficiency. As a result, it is possible to improve a throughput of the substrate processing apparatus 600.

In addition, in the substrate processing apparatus 600, the third transfer robot 664 is provided with the pair of arms 164a and 164b. Therefore, by controlling each of the arms 164a and 164b independently, it is possible to improve the transfer efficiency of the substrate S. For example, each of the substrates S can be moved from the reactor 300a to the intermediate structure 160 and moved from the intermediate structure 160 to the reactor 300b or the second transfer structure 140 at the same time.

In addition, in the substrate processing apparatus 600, when it is not desirable to bring a component of the gas used in the reactor 300a into the reactor 300b, by dividing roles of the pair of arms 164a and 164b into the arm for the reactor 300a and the arm for the reactor 300b, respectively, it is possible to prevent the component of the gas used in the reactor 300a from being brought into the reactor 300b.

In addition, the third transfer robot 664 may be provided with three or more arms.

For example, the embodiments mentioned above are described by way of an example in which the film forming process is performed as the substrate processing performed by the substrate processing apparatuses mentioned above. However, the technique of the present disclosure is not limited thereto. That is, the technique of the present disclosure can be applied not only to the film forming process of forming the film exemplified in the embodiments mentioned above but also to a film forming process of forming another film or a modification process. For example, the specific contents of the substrate processing are not limited to those exemplified in the embodiments mentioned above. For example, in addition to or instead of the film forming process or modification process mentioned above, the technique of the present disclosure may be applied to a process such as an annealing process, a diffusion process, an oxidation process, a nitridation process and a lithography process. In addition, the technique of the present disclosure may also be applied to other substrate processing apparatuses such as an annealing apparatus, an etching apparatus, an oxidation apparatus, a nitridation apparatus, an exposure apparatus, a coating apparatus, a drying apparatus, a heating apparatus, and an apparatus using the plasma. The technique of the present disclosure may also be applied when a constituent of one of the embodiments mentioned above is substituted with another constituent of another embodiment, or when a constituent of one of the embodiments mentioned above is added to another embodiment. In addition, the technique of the present disclosure may also be applied when the constituent of the embodiments mentioned above is omitted or substituted, or when a constituent added to the embodiments mentioned above.

In the embodiments described above, for convenience of explanation, the inert gas supplier 371 is commonly used. However, the technique of the present disclosure is not limited thereto. For example, the inert gas supplier 371 may be provided separately for each configuration to which the inert gas supplier 371 is connected.

According to some embodiments of the present disclosure, it is possible to improve the productivity of the substrate processing.

What is claimed is:

1. A substrate processing apparatus comprising:
an atmospheric transfer structure configured to transfer a substrate in an atmospheric atmosphere;
a plurality of processing structures arranged along the atmospheric transfer structure and configured to be capable of processing the substrate in a vacuum atmosphere; and
an intermediate structure arranged adjacent to the plurality of processing structures, and configured to receive the substrate from the atmospheric transfer structure and to transfer the substrate to each of the plurality of processing structures in an atmosphere whose pressure is lower than that of the atmospheric atmosphere.

2. The substrate processing apparatus of claim 1, further comprising:
an intermediate transfer robot provided in the intermediate structure and capable of transferring the substrate into the intermediate structure; and
a controller,
wherein each of the plurality of processing structures is provided with a loading port communicating with the intermediate structure and an unloading port communicating with the atmospheric transfer structure, and
wherein the controller is configured to be capable of controlling the intermediate transfer robot such that an unprocessed substrate in the intermediate structure is loaded from the intermediate structure into a processing structure among the plurality of processing structures through the loading port related to the processing structure, and such that a processed substrate for which a processing is completed in the processing structure is unloaded from the processing structure to the atmospheric transfer structure through the unloading port related to the processing structure.

3. The substrate processing apparatus of claim 1, further comprising:
an intermediate transfer robot provided in the intermediate structure and capable of transferring the substrate within the intermediate structure.

4. The substrate processing apparatus of claim 3, wherein each of the plurality of processing structures comprises: a first processing structure; and a second processing structure with the intermediate structure disposed therebetween, and
wherein a housing constituting the intermediate structure comprises:
a first wall adjacent to the first processing structure;
a second wall adjacent to the second processing structure;
a third wall adjacent to the atmospheric transfer structure; and
a fourth wall disposed in a position opposite to the third wall, and
wherein an arm of the intermediate transfer robot is allowed to rotate within a space surrounded by the first wall, the second wall and the third wall but is prevented from rotating in a direction from the first wall or the second wall toward the fourth wall.

5. The substrate processing apparatus of claim 3, wherein the intermediate structure is configured such that an inner atmosphere of the intermediate structure returns from an atmosphere whose pressure is lower than that of the atmospheric atmosphere to the atmospheric atmosphere while the intermediate transfer robot is supporting a processed substrate.

6. The substrate processing apparatus of claim 3, further comprising:
a standby structure provided in the intermediate structure,
wherein the substrate is in standby in the standby structure.

7. The substrate processing apparatus of claim 6, wherein the standby structure is capable of supporting the substrate and one or more substrates.

8. The substrate processing apparatus of claim 7, wherein the substrate and the one or more substrates are capable of being stacked in the standby structure, and
wherein the standby structure and the intermediate transfer robot are configured to be capable of being moved relatively in an up-down direction.

9. The substrate processing apparatus of claim 6, further comprising:
a controller,
wherein each of the plurality of processing structures is provided with a substrate support capable of supporting the substrate and one or more substrates, and
wherein the controller is configured to be capable of controlling the intermediate transfer robot such that the substrate is transferred to the standby structure when the number of substrates capable of being supported by the substrate support is greater than the number of substrates capable of being transferred by the intermediate transfer robot.

10. The substrate processing apparatus of claim 1, wherein each of the plurality of processing structures comprises: a first processing structure; and a second processing structure with the intermediate structure disposed therebetween, and
wherein a housing constituting the intermediate structure comprises:
a first wall adjacent to the first processing structure;
a second wall adjacent to the second processing structure;
a third wall adjacent to the atmospheric transfer structure; and
a fourth wall disposed in a position opposite to the third wall, and
wherein a first loading/unloading port is provided on the third wall and second loading/unloading ports are provided respectively on the first wall and the second wall, and each of the second loading/unloading ports is arranged at a lateral position with respect to an entrance direction of the substrate to be loaded through the first loading/unloading port.

11. The substrate processing apparatus of claim 1, wherein each of the plurality of processing structures is provided with a loading/unloading port communicating with the intermediate structure, and
wherein each of the plurality of processing structures comprises:
a transfer chamber where the loading/unloading port is provided; and
a process chamber provided above the transfer chamber and made of quartz.

12. The substrate processing apparatus of claim 1, wherein a plurality of combinations, each of which is constituted by the intermediate structure and the plurality of processing structures, are arranged along the atmospheric transfer structure.

13. The substrate processing apparatus of claim 12, wherein the intermediate structure is arranged between the plurality of processing structures in each of the plurality of combinations.

14. The substrate processing apparatus of claim 12, wherein:
each of the plurality of processing structures comprises: a first processing structure; and a second processing structure with the intermediate structure disposed therebetween;
the plurality of combinations are arranged along the atmospheric transfer structure; and
in locations where two combinations among the plurality of combinations are adjacent to each other, positions of the first processing structure and the second processing structure in each of the two combinations are set such that the first processing structure of one of the two combinations is adjacent to the second processing structure of the other of the two combinations.

15. The substrate processing apparatus of claim 1, wherein each of the plurality of processing structures comprises: a first processing structure; and a second processing structure with the intermediate structure disposed therebetween, and
wherein a plurality of combinations, each of which is constituted by the first processing structure, the second processing structure and the intermediate structure, are arranged so as to be point symmetrical at positions facing one another with the atmospheric transfer structure interposed therebetween.

16. The substrate processing apparatus of claim 1, further comprising:
an atmospheric transfer robot provided in the atmospheric transfer structure and capable of transferring the substrate into the intermediate structure; and
an intermediate transfer robot provided in the intermediate structure and capable of transferring the substrate into each of the plurality of processing structures,
wherein the substrate is transferred from the atmospheric transfer robot to the intermediate transfer robot, or transferred from the intermediate transfer robot to the atmospheric transfer robot.

17. The substrate processing apparatus of claim 1, wherein the intermediate structure is further provided with a cooling structure capable of cooling the processed substrate.

18. A substrate processing method comprising:
(a) accommodating a substrate transferred from an atmospheric transfer structure in an atmospheric atmosphere in an intermediate structure arranged along the atmospheric transfer structure;
(b) transferring the substrate from the intermediate structure in an atmosphere whose pressure is lower than that of the atmospheric atmosphere to a processing structure arranged adjacent to the intermediate structure; and
(c) processing the substrate in the processing structure.

19. A method of manufacturing a semiconductor device, comprising:
the method of claim 18.

20. A non-transitory computer-readable recording medium storing a program that causes a substrate processing apparatus, by a computer, to perform:
(a) accommodating a substrate transferred from an atmospheric transfer structure in an atmospheric atmosphere in an intermediate structure arranged along the atmospheric transfer structure;
(b) transferring the substrate from the intermediate structure in an atmosphere whose pressure is lower than that of the atmospheric atmosphere to a processing structure arranged adjacent to the intermediate structure; and
(c) processing the substrate in the processing structure.
